(19) United States
(12) Patent Application Publication
(10) Pub. No.: US 2026/0181976 A1
(43) Pub. Date: Jun. 25, 2026

(54) Semiconductor Device and Method of Fabricating the Same

(71) Applicant: UNITED MICROELECTRONICS CORP., Hsin-Chu City (TW)

(72) Inventors: Chun-Liang Kuo, Kaohsiung City (TW); Chung-Yi Chiu, Tainan City (TW); Tsung-Mu Yang, Tainan City (TW); Yu-Ren Wang, Tainan City (TW); Chen-Chih Hsu, Kaohsiung City (TW); Yung-Chen Tsai, Tainan City (TW); Yu-Jui Kao, Tainan City (TW); Tzu-Hsuan Sun, Tainan City (TW); Wei-Renn Tang, Tainan City (TW)

(73) Assignee: UNITED MICROELECTRONICS CORP., Hsin-Chu City (TW)

(21) Appl. No.: 19/046,538

(22) Filed: Feb. 6, 2025

(30) Foreign Application Priority Data
Dec. 24, 2024 (TW) 113150342

(51) Int. Cl. H10D 62/10; H10D 62/00; H10D 84/01; H10D 84/83

(52) U.S. Cl. CPC H10D 62/116; H10D 62/021; H10D 84/013; H10D 84/0151; H10D 84/8312

(57) ABSTRACT

The present disclosure relates to a semiconductor device and a method of fabricating the same including a substrate, a first gate structure, two first source/drain structures, and an air barrier layer. The substrate includes at least one shallow trench isolation disposed therein. The first gate structure is disposed on the substrate. Two first source/drain structures are disposed in the substrate, at two sides of the first gate structure, and a side of each of the two first source/drain structures is adjacent to the at least one shallow trench isolation. The air gap barrier layer is disposed between the substrate and each of the two first source/drain structures, wherein the air gap barrier layer includes a bottom surface and two sidewalls each extending in three different directions.

### BACKGROUND OF THE INVENTION

### 1. Field of the Invention

The present disclosure relates generally to a semiconductor device and a method of fabricating the same, and more particularly to a semiconductor device including an epitaxial structure and a method of fabricating the same.

### 2. Description of the Prior Art

For the sake of increasing the carrier mobility of the semiconductor structure, a compressive stress or tensile stress can be optionally applied to the gate channel. In conventional arts, a selective epitaxial growth (SEG) process is used to form a compressive stress. For example, after the formation of a gate on a silicon substrate, a silicon-germanium (SiGe) epitaxial structure is formed in the predetermined location, in which the lattice arrangement of silicon (Si) and germanium (Ge) are similar to each other. Since the lattice constant of the SiGe layer is larger than a lattice constant of Si, accordingly, the band structure of Si may be changed, and the compressive stress is then formed and applied to the channel region of a PMOS transistor, thereby increasing the carrier mobility in the channel region, as well as increasing the efficiency of the PMOS transistor. On the other hand, a silicon carbide (SiC) epitaxial structure can be optionally formed in the silicon substrate of a NMOS transistor, to apply the tensile stress to the channel region of the NMOS transistor. However, while the foregoing method can improve the carrier mobility in the channel region, said method also has led to the difficulty of the overall fabrication process and the process control, especially under the trend of miniaturization of semiconductor device dimensions. Hence, there is a need of proving a novel fabrication method of a semiconductor structure, to obtain more reliable semiconductor device.

### SUMMARY OF THE INVENTION

An object of the present disclosure is to provide a semiconductor device where an air barrier layer is additionally disposed under a source/drain structure having an epitaxial material. Through arranging the air barrier layer with the bottom surface and the sidewalls thereof extending in different directions, the current leakage issue will be improved by effectively blocking the currents possibly leaking from the bottom of the source/drain structure, and then, the operating performance and the device function of the semiconductor device are all enhanced thereby.

Another object of the present disclosure is to provide a method of fabricating a semiconductor device, in which an air barrier layer is additionally formed below a source/drain structure having an epitaxial material. Through arranging the air barrier layer with the bottom surface and the sidewalls thereof extending in different directions, the current leakage issue will be improved by effectively blocking the currents possible leaking from the bottom of the source/drain structure, and then, the operating performance and the device function of the semiconductor device are all enhanced thereby.

To achieve the aforementioned objects, the present disclosure provides a semiconductor device including a substrate, a first gate structure, two first source/drain structures and an air barrier layer. The substrate includes at least one shallow trench isolation disposed therein. The first gate structure is disposed on the substrate. The first source/drain structures are disposed in the substrate, at two sides of the first gate structure, and a side of each of the two first source/drain structures is adjacent to the at least one shallow trench isolation. The air barrier layer is disposed between the substrate and each of the two first source/drain structures, wherein the air barrier layer includes a bottom surface and two sidewalls extending in three different directions, respectively.

To achieve the aforementioned objects, the present disclosure provides a method of fabricating a semiconductor device, including the following steps. A substrate is provided, and the substrate includes at least one shallow trench isolation disposed therein.

A first gate structure is formed on the substrate. Two first source/drain structures are formed in the substrate, at two sides of the first gate structure, wherein a side of each of the two first source/drain structures is adjacent to the at least one shallow trench isolation. An air barrier layer is formed between the substrate and each of the two first source/drain structures, wherein the air barrier layer includes a bottom surface and two sidewalls extending in three different directions, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic cross-sectional diagram of a semiconductor device according to a first embodiment of the present disclosure.

FIG. 2 to FIG. 9 illustrate schematic diagrams of a method of fabricating a semiconductor device according to a first embodiment of the present disclosure, in which:

FIG. 2 is a schematic cross-sectional view of a semiconductor device after forming an insulating layer;

FIG. 3 is a schematic cross-sectional view of a semiconductor device after forming recesses;

FIG. 4 is a schematic cross-sectional view of a semiconductor device after forming a semiconductor material layer;

FIG. 5 is a schematic cross-sectional view of a semiconductor device after forming a shallow trench isolation;

FIG. 6 is a schematic cross-sectional view of a semiconductor device after partially removing the semiconductor material layer;

FIG. 7 is a schematic cross-sectional view of a semiconductor device after forming an etching stop material layer;

FIG. 8 is a schematic cross-sectional view of a semiconductor device after forming a first dielectric material layer; and

FIG. 9 is a schematic cross-sectional view of a semiconductor device after forming a second dielectric material layer.

FIG. 10 illustrates a schematic cross-sectional diagram of a semiconductor device according to a second embodiment of the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

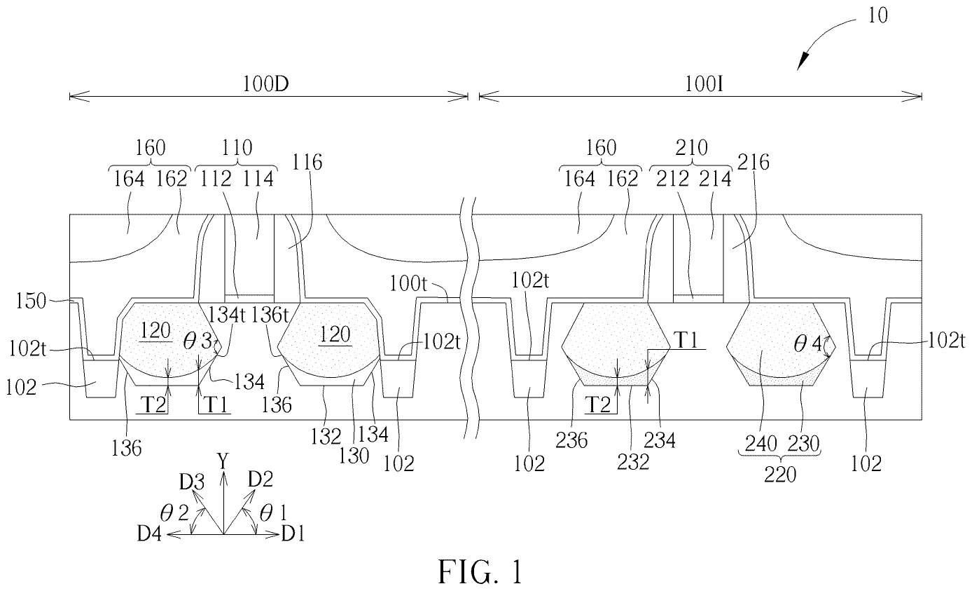

Please refer to FIG. 1, which is a schematic diagram of a semiconductor device 10 according to a first embodiment of the present disclosure. The semiconductor device 10 includes a substrate 100, a first gate structure 110 disposed on the substrate 100, and two first source/drain structures 120 and an air barrier layer 130 all disposed within the substrate 100. The substrate 100 for example includes a silicon substrate, an epitaxial silicon substrate, a silicon containing substrate or a silicon-on-insulator (SOI) substrate, and the substrate 100 may further include at least one shallow trench isolation 102 disposed therein. In one embodiment, a plurality of the shallow trench isolations 102 is disposed within the substrate 100, and each includes a top surface 102t which is lower than a top surface 100t of the substrate 100. The two first source/drain structures 120 are respectively disposed at two opposite sides of the first gate structure 110, with each of the two first source/drain structures 120 disposed adjacent to one shallow trench isolation 102 also disposed at two opposite sides of the first gate structure 110, as shown in FIG. 1.

It is noted that the air barrier layer 130 is disposed between the substrate 100 and each of the two first source/drain structures 120 in a vertical direction “Y” being perpendicular to the substrate 100, and which includes a bottom surface 132 and two sidewalls 134, 136 extending in three different directions D1, D2, D3, respectively, for fully blocking the bottom of each first source/drain structure 120. Through this arrangement, the air barrier layer 130 enables to isolate the possible contacts between the bottom of each first source/drain structure 120 and the substrate 100 in an effective manner through blocking the currents leaking through the bottom of the first source/drain structure 120 to the substrate 100, so as to improve the decreased Isub issue.

Precisely speaking, the bottom surface 132 of the air barrier layer 130 for example extends in the direction D1 being parallel to the substrate 100, and the two sidewalls 134, 136 of the air barrier layer 130 respectively extend toward two directions D2, D3 each is different from and is not perpendicular to the direction D1. That is, the air barrier layer 130 directly contacts the bottom of each first source/drain structure 120 and includes an extending area which is not smaller than the bottom of each first source/drain structure 120 in the direction D1, so as to effectively prevent from the current leakage. The directions D2, D3 each has an included angle θ1, θ2 respective to the direction D1 or a reverse direction D4 thereof, and the included angle θ1, θ2 is about 52 to 54 degrees, but not limited thereto. In one embodiment, the air barrier layer 130 for example includes a thickness being partially increased or partially decreased, such that, the air barrier layer 130 includes a thickness T1 at two ends thereof and a thickness T2 at the middle thereof, and the thickness T1 is preferably larger than the thickness T2, to achieve the better isolation.

On the other hand, each first source/drain structure 120 and the air barrier layer 130 disposed underneath may together present in a cross-sectional shape like a hexagon or an octagon. Each first source/drain structure 120 for example includes an included angle θ3 on a sidewall thereof, with the included angle θ3 being disposed below the first gate structure 110 and a spacer 116 disposed on the sidewall of the first gate structure 110 in the vertical direction “Y”. That is, the included angle θ3 is located higher than the top surface 102t of the shallow trench isolation 102 and is lower than the top surface 100t of the substrate 100, and tips 134t, 136t of the two sidewalls 134, 136 of the air barrier layer 130 are preferably both higher than the surface 102t of the shallow trench isolation 102 and lower than the included angle θ3 in the vertical direction “Y”, as shown in FIG. 1. In one embodiment, the included angle θ3 is for example in about 120-130 degrees, but not limited thereto. In another embodiment, each first source/drain structure 120 for example includes a semiconductor material, and the material of the semiconductor material may be adjusted according to the type of a MOS transistor based on the first gate structure 110 in the subsequent process. For example, the first source/drain structures 120 for example include a material like silicon germanium (SiGe), boron germanium silicide (SiGeB) or tin germanium silicide (SiGeSn), and preferably include a proper P-type dopant, while a PMOS transistor is subsequently formed based on the first gate structure 110. Otherwise, the first source/drain structures 120 may also include a material like silicon carbide (SiC), silicon phosphide (SiP) or silicon carbonitride (SiCP), and preferably include a proper N-type dopant, while a NMOS transistor is subsequently formed based on the first gate structure 110.

Further in view of FIG. 1, the semiconductor device 10 further includes a second gate structure 210 disposed on the substrate 100, and two second source/drain structures 220 disposed within the substrate 100. The two second source/drain structures 220 are for example disposed at two opposite sides of the second gate structure 210, within the substrate 100, and with each of the two second source/drain structures 220 being closed to and not in direct contact with the shallow trench isolations 102 also disposed at the two opposite sides of the second gate structure 210. In one embodiment, the substrate 100 further includes a dense region 100D and an iso region 100I disposed thereon, and the first gate structure 110 and the two first source/drain structures 120 are both disposed within the dense region 100D, and the second gate structure 210 and the two second source/drain structures 220 are both disposed within the iso region 100I, but not limited thereto.

The first gate structure 110 and the second gate structure 210 respectively includes a gate dielectric layer 112/212, and an electrode layer 114/214, and a spacer 116 is additionally disposed on the sidewall of the first gate structure 110, and a spacer 216 is additionally disposed on the sidewall of the second gate structure 210. In one embodiment, the gate dielectric layer 112 of the first gate structure 110 and the gate dielectric layer 212 of the second gate structure 210 for example include a dielectric material like silicon oxide, the electrode layer 114 of the first gate structure 110 and the electrode layer 214 of the second gate structure 210 for example include a semiconductor material like doped polysilicon or doped amorphous silicon, and the spacer 116 and the spacer 216 for example each includes a monolayer structure or a multilayer structure including an insulating material like silicon nitride, silicon oxynitride or silicon carbonitride, but not limited thereto. Each of the second source/drain structures 220 also includes a cross-sectional shape like a hexagon or an octagon, and an included angle θ4 on a sidewall thereof, and the included angle θ4 is about 120-130 degrees, but not limited thereto. In one embodiment, each of the second source/drain structures 220 further includes a first semiconductor layer 230 and a second semiconductor layer 240 stacked in sequence, with the first semiconductor layer 230 and the second semiconductor layer 240 including semiconductor materials having etching selectivity therebetween. For example, the first semiconductor layer 230 for example includes silicon germanium, and the second semiconductor layer 240 includes a semiconductor material with etching selectivity respective to silicon germanium. Preferably, the material selection of the second semiconductor layer 240 may be adjusted according to the type of the subsequently formed MOS transistor based on the first gate structure 110. For example, the second semiconductor layer 240 for example includes a material like silicon germanium, boron germanium silicide or tin germanium silicide with a relative greater concentration of germanium, and preferably include a proper P-type dopant, while a PMOS transistor is subsequently formed based on the first gate structure 110. Otherwise, the second semiconductor layer 240 for example include a material like silicon carbide, silicon phosphide or silicon carbonitride, and preferably include a proper N-type dopant, while a NMOS transistor is subsequently formed based on the first gate structure 110, but not limited thereto.

It is noted that, the first semiconductor layer 230 also includes a bottom surface 232 and two sidewalls 234, 236 extending along the three different directions D1, D2, D3, respectively, and a thickness being partially increased or partially decreased. The first semiconductor layer 230 right below the second semiconductor layer 240 includes a thickness T1 at two ends thereof, with the thickness T1 of the second semiconductor layer 240 being the same as the thickness T1 of the air barrier layer 130, and a thickness T2 at the middle of the first semiconductor layer 230, with the thickness T2 of the second semiconductor layer 240 being the same as the thickness T2 of the air barrier layer 130, and the thickness T1 of the second semiconductor layer 240 is preferably larger than the thickness T2 of the second semiconductor layer 240, but not limited thereto. That is, the first semiconductor layer 230 of each of the second source/drain structures 220 disposed within the iso region 100I has the same cross-sectional structure as the air barrier layer 130 disposed within the dense region 100D, with the bottom surface 132 of the air barrier layer 130 and the bottom surface 232 of the first semiconductor layer 230 both extending in the direction D1, with the sidewall 134 of the air barrier layer 130 and the sidewall 234 of the first semiconductor layer 230 both extending in the direction D2, and with the sidewall 136 of the air barrier layer 130 and the sidewall 236 of the first semiconductor layer 230 both extending in the direction D3, as shown in FIG. 1.

Furthermore, the semiconductor device 10 further includes an etching stop layer (CESL) 150 and an interlayer dielectric layer 160. The etching stop layer 150 conformally overlays the top surface 102t of the shallow trench isolation 102, the sidewall of the first gate structure 110, the first source/drain structures 120, the sidewall of the second gate structure 210, and the second source/drain structures 220, to expose the top surfaces of the first gate structure 110 and the second gate structure 210. The interlayer dielectric layer 160 further overlays the etching stop layer 150, and precisely includes a first dielectric layer 162 and a second dielectric layer 164 stacked in sequence, and a portion of the etching stop layer 150 which is directly on the top surface 102t of the shallow trench isolation 102 and a portion of the first dielectric layer 162 which is directly on the portion of the etching stop layer 150 are both disposed within the substrate 100. In one embodiment, the etching stop layer 150 for example includes a dielectric material like silicon nitride, or silicon carbonitride, and the first dielectric layer 162 and the second dielectric layer 164 respectively include dielectric materials with different etching selectivity, like silicon oxide or tetraethyl orthosilicate (TEOS), but not limited thereto.

According to the semiconductor device 10 of the present embodiment, the air barrier layer 130 is additionally disposed under each first source/drain structure 120 within the dense region 100D, with the bottom surface 132 and the sidewalls 134, 136 thereof respectively extending in different directions D1, D2, D3, to effectively isolate the possible contact between the bottom of each first source/drain structure 120 and the substrate 100, and to block the currents that may leak from the bottom of each first source/drain structure 120 to the substrate 100 thereby. In this way, the semiconductor device 10 of the present embodiment is allowable to avoid the current leakage from the substrate 100 by additionally arranging the air barrier layer 130, so as to improve the decreased Isub, and also to enhance the operating performance and the efficiency of the semiconductor device 10.

In order to make people skilled in the art of the present disclosure easily understand the semiconductor device 10 of the present disclosure, a fabricating method of the semiconductor device 10 in the present disclosure will be further described below.

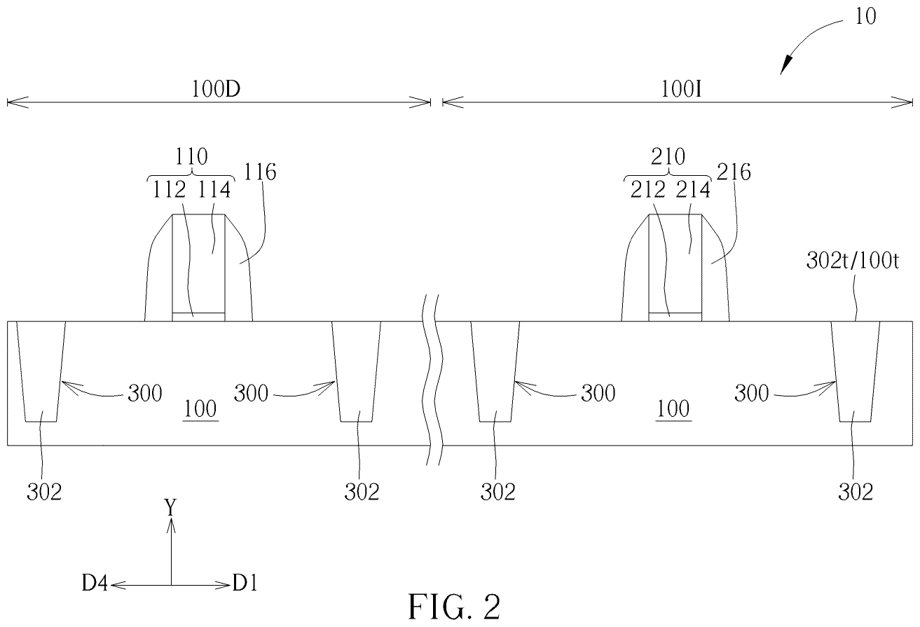

Please refer to FIG. 2 to FIG. 9, which illustrate a method of fabricating a semiconductor device 10 according to the first embodiment of the present disclosure. As shown in FIG. 2, the substrate 100 is provided, for example being a silicon substrate, an epitaxial silicon substrate, a silicon containing substrate or a silicon-on-insulator (SOI) substrate, and an insulating layer 302 is formed within the substrate 100, and the first gate structure 110 and the second gate structure 210 are both formed on the substrate 100. In one embodiment, the formation of the insulating layer 302 for example includes first forming a plurality of shallow trenches 300 in the substrate, filling in an insulating material like silicon oxide or silicon oxynitride in the shallow trenches 300, and followed by performing a planarization process to partially remove the insulating material. Then, the insulating layer 302 is formed in each of the shallow trenches 300, with a top surface 302t being coplanar with the top surface 100t of the substrate 100

On the other hands, the formation of the first gate structure 110 and the second gate structure 210 includes but not limited to the following steps. Firstly, a gate dielectric material layer (not shown in the drawings) for example including a dielectric material like silicon oxide, and a gate material layer (not shown in the drawings) for example including a semiconductor material like doped polysilicon or doped amorphous silicon are sequentially formed on the top surface 100t of the substrate 100. Next, a patterning process is performed on the gate dielectric material layer and the gate material layer, to form the first gate structure 110 (including the gate dielectric layer 112 and the electrode layer 114 stacked in sequence) and the second gate structure 210 (including the gate dielectric layer 212 and the electrode layer 214 stacked in sequence) respectively within the dense region 100D and the iso region 100I of the substrate 100. Then, a deposition process and an etching back process are performed, to form the spacer 116 on the sidewall of the first gate structure 110, and to form the spacer 216 on the sidewall of the second gate structure 210, with the spacer 116 and the spacer 216 each including an insulating material like silicon nitride, silicon oxynitride or silicon carbonitride, and optionally including a monolayer structure or a multilayer structure. In one embodiment, two light doped drain regions (LDD, not shown in the drawings) may be further formed at two sides of the first gate structure 110 and the second gate structure 210 within the substrate 100, through using the first gate structure 110 and the second gate structure 210 as a mask for implantation, followed by forming the spacer 116 and the spacer 216.

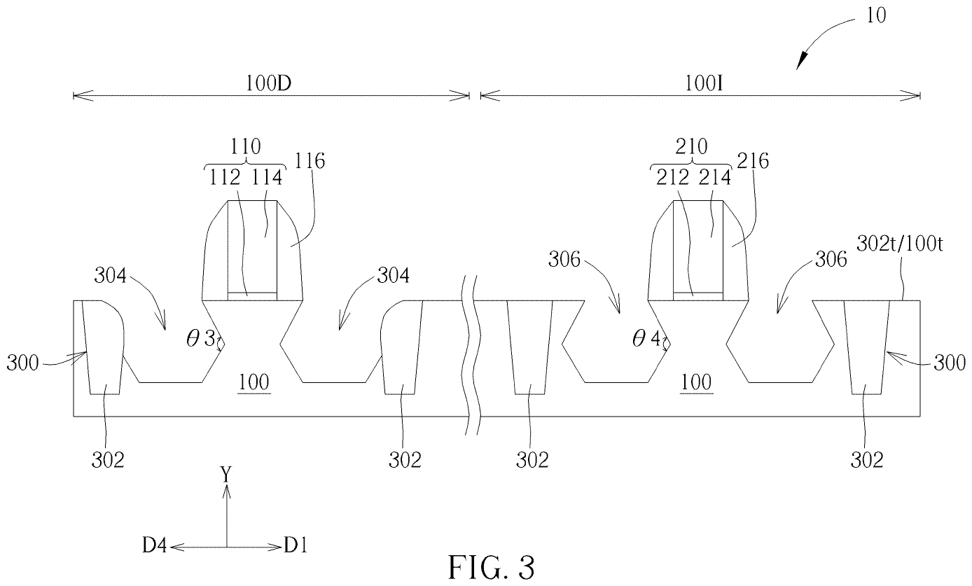

As shown in FIG. 3, an etching process is performed through a mask layer (not shown in the drawings), to form two recesses 304 at two sides of the first gate structure 110 and two recesses 306 in the substrate 100 at two sides of the second gate structure 210, and the mask layer is then removed. Precisely speaking, the etching process for example includes first performing a dry etching process, to vertically etch the substrate 100 at both two sides of the first gate structure 110 and at both two sides of the second gate structure 210 to form primary recesses (not shown in the drawings), and next performing a wet etching process, to isotropically enlarge the primary recesses along lattice plane <111> of the substrate 100 to form the recesses 304, 306 in various cross-sectional shapes. In one embodiment, the wet etching is performed for example by using an etchant including ammonium hydroxide (NH₄OH) or tetramethylammonium hydroxide (TMAH), but not limited thereto. In the present embodiment, each of the recesses 304, 306 is exemplified as a hexagonal cross-section, with the sidewall of each of recesses 304, 306 includes the included angle θ3, θ4 being about 120-130 degrees, but not limited thereto. In other embodiments, each of the recesses 304, 306 may also be formed in an octagonal cross-section (not shown in the drawings) or an arc cross-section (not shown in the drawings), due to practical process requirements. It should be easily understood by those skilled in the art that the recesses 304, 306 are not limited to be formed through sequentially performing the dry etching and the wet etching, and which may also be formed through performing a single or multiple dry etching and/or wet etching according to practical requirements.

It is noted that due to the density of the predetermined components formed within the dense region 100D being greater than that within the iso region 100I, the location of each recess in the dense region 100D which is defined by the mask layer may be partially overlap with the edge of the insulating layer 302 disposed at both two sides of the first gate structure 110. Accordingly, when the etching process is performed, each of the recesses 304 formed at both two sides of the first gate structure 110 will not present in a complete hexagonal cross-section because of the interference of the insulating layer 302. Also, the edge of the insulating layer 302 will be partially etched while the etching process is performed, as shown in FIG. 3. On the other hands, the location of each recess in the iso region 100I which is defined by the mask layer does not overlap with the edge of the insulating layer 302 disposed at both two sides of the second gate structure 210, and each of the recesses 306 formed at both two sides of the second gate structure 210 will present in a complete hexagonal cross-section.

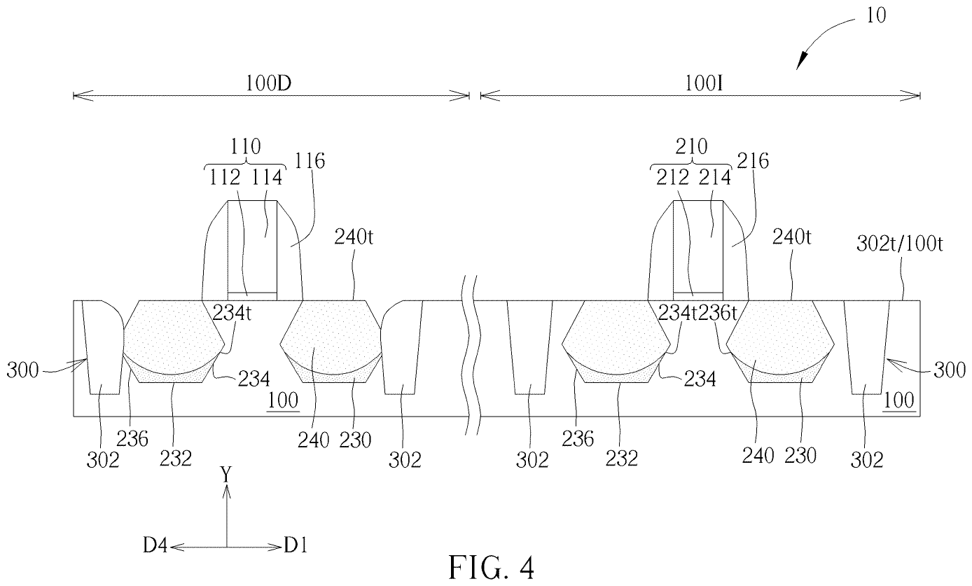

As shown in FIG. 4, a selective epitaxial growth (SEG) process is performed to form the first semiconductor layer 230 and the second semiconductor layer 240 stacked in sequence in each of the recesses 304, 306. Precisely speaking, the selective epitaxial growth process is carried out by first performing a first epitaxial growth process, to confine the growth of the first semiconductor layer 230 only at the bottom of each of the recesses 304, 306 by adjusting the growing rate and the lattice plane thereof, and next performing a second epitaxial growth process, to fill up each of the recesses 304, 306 by forming the second semiconductor layer 240 on the first semiconductor layer 230. Accordingly, a top surface 240t of the second semiconductor layer 240 formed within each of the recesses 304, 306 will be coplanar with the top surface 100t of the substrate 100. It is noted that, the first semiconductor layer 230 and the second semiconductor layer 240 formed within the dense region 100D will also not present in a complete hexagonal cross-section according to the shape of each recess 304, and he first semiconductor layer 230 and the second semiconductor layer 240 formed within the iso region 100I will together present in the same hexagonal cross-section as that of each recess 306.

In addition, the first semiconductor layer 230 formed within each of the recesses 304, 306 includes the bottom surface 232 and the two sidewalls 234, 236 extending in the three different directions D1, D2, D3, respectively, and tips 234t, 236t of the two sidewalls 234, 236 of the are preferably both lower than the included angle θ3, θ4 in the vertical direction “Y”. In one embodiment, the first semiconductor layer 230 for example includes a semiconductor material like silicon germanium and the second semiconductor layer 240 for example includes a semiconductor material having an etching selectivity respective to silicon germanium. For example, the material selection of the second semiconductor layer 240 may be adjusted according to the type of the subsequently formed MOS transistor based on the first gate structure 110. If a PMOS transistor is formed then, and the second semiconductor layer 240 may include a material like silicon germanium, boron germanium silicide or tin germanium silicide with a relative higher concentration of germanium. Otherwise, if a NMOS transistor is formed then, and the second semiconductor layer 240 may include a material like silicon carbide, silicon phosphide or silicon carbonitride, but not limited thereto. In one embodiment, an ion implantation process may performed after forming the second semiconductor layer 240 or the ion implantation process may be in-situ performed while forming the second semiconductor layer 240, to implant a proper N-type dopant or a proper P-type dopant in the second semiconductor layer 240. Also, in another embodiment, the N-type P-type dopants may either be altered in a gradual arrangement, but not limited thereto.

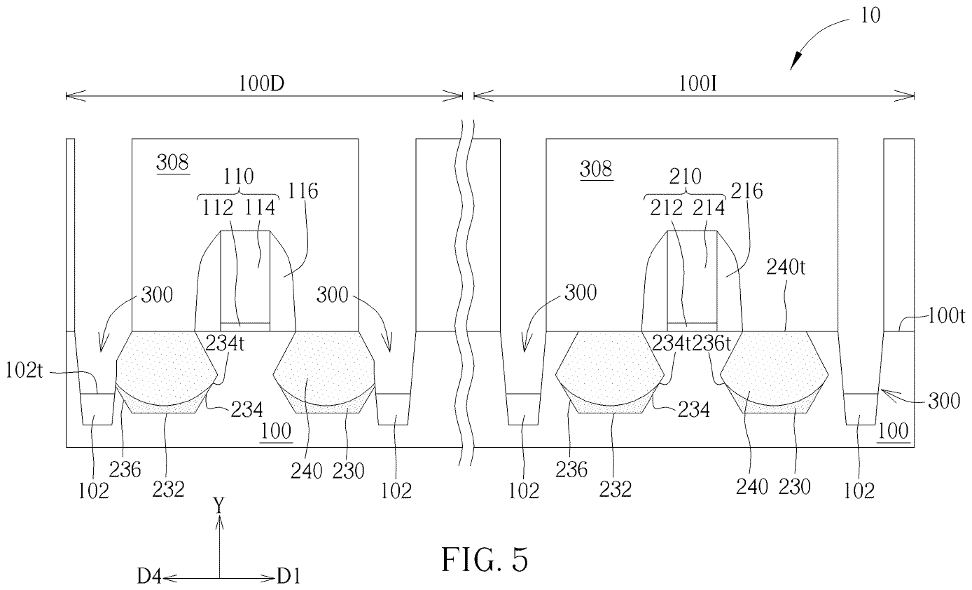

As shown in FIG. 5, a mask layer 308 is formed on the substrate 100, covering the top surface 204t of the second semiconductor layer 240, the first gate structure 110 and the second gate structure 210, and a wet etching process is next performed to partially remove the insulating layer 302 filled in the shallow trenches 300 till not filling up each shallow trench 300, to form the shallow trench isolation 102 with the top surface 102t being lower than the top surface 100t of the substrate 100. Through these performances, the top surface 102t of the shallow trench isolation 102 is lower than the tips 234t, 236t of the first semiconductor layer 230, such that, the first semiconductor layer 230 formed within the dense region 100D will therefore be partially exposed from each shallow trench 300.

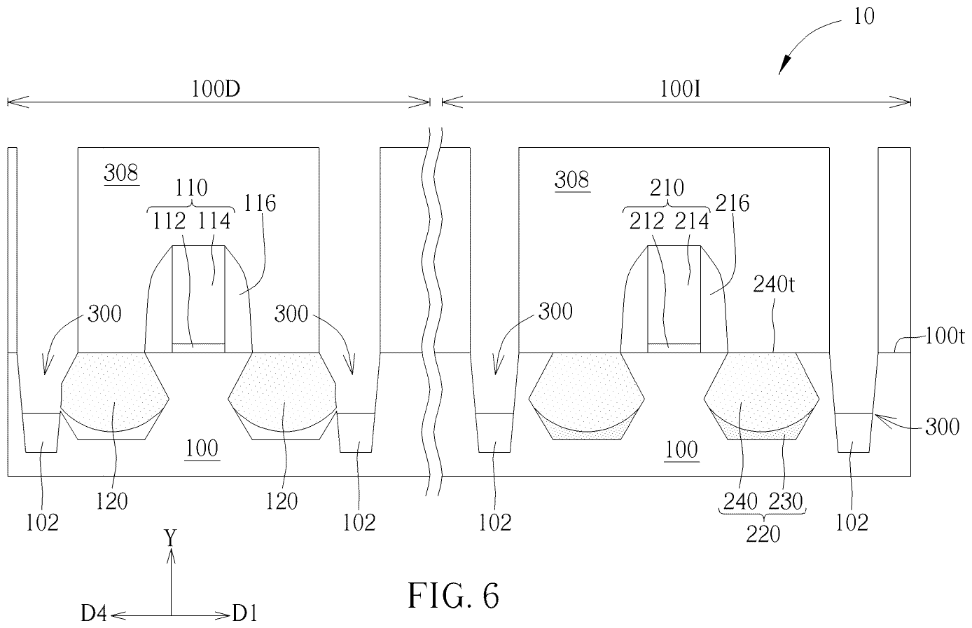

As shown in FIG. 6, another wet etching process is performed through the mask layer 308, by using an etchant like hydrochloric acid (HCl) to selectively etch the first semiconductor layer 230 from the portion being exposed from the shallow trench 300 within the dense region 100D. Accordingly, the first semiconductor layer 230 is completely removed, and an air gap is formed under the second semiconductor layer 240 within the dense region 100D.

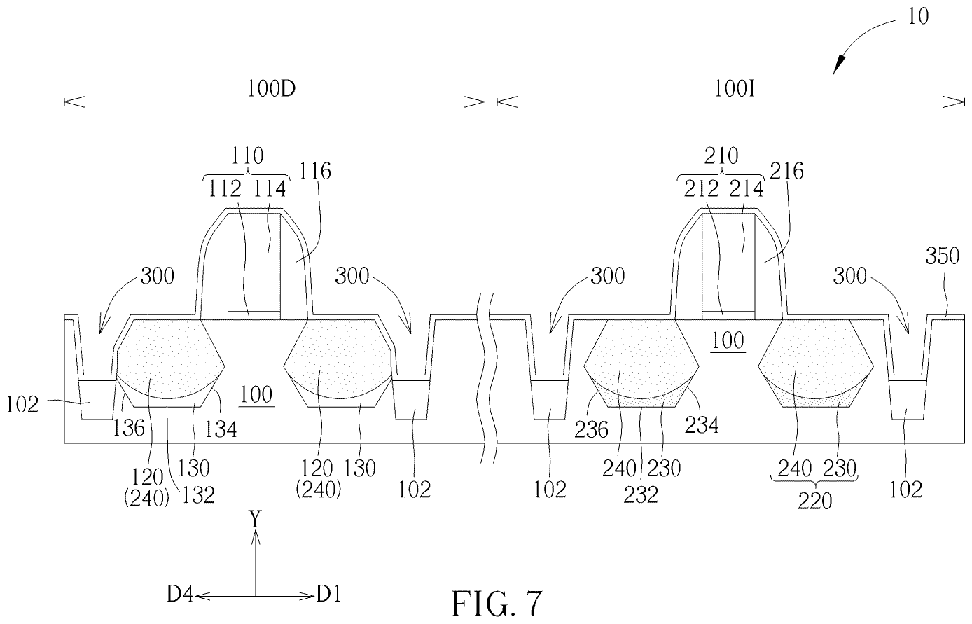

As shown in FIG. 7, after completely removing the mask layer 308, an etching stop material layer 350 is formed on the substrate 100 to overlay the substrate 100, the first gate structure 110, and the second gate structure 210 in a conformal manner. In one embodiment, the etching stop material layer 350 for example includes a material like silicon nitride or silicon carbonitride, but is not limited thereto. It is noted that, a portion of the etching stop material layer 350 further extends into each shallow trench 300, to overlay the upper sidewall of each shallow trench 300 and the top surface 102t of the shallow trench isolation 102. Then, the air gap formed within the dense region 100D will be sealed by the etching stop material layer 350, thereby forming the air barrier layer 130 as shown in FIG. 1, and the second semiconductor layer 240 formed above the air barrier layer 130 will therefore form the first source/drain structure 120 as shown in FIG. 1. On the other hand, the first semiconductor layer 230 and the second semiconductor layer 240 formed within the iso region 100I will together form the second source/drain structure 220 as shown in FIG. 1 at the same time. Through these performances, the first semiconductor layer 230 of the second source/drain structure 220 formed within the iso region 100I and the air barrier layer 130 formed within the dense region 100D will both include the same cross-sectional shape, with the bottom surface 132 of the air barrier layer 130 and the bottom surface 232 of the first semiconductor layer 230 both extending in the direction D1, with the sidewall 134 of the air barrier layer 130 and the sidewall 234 of the first semiconductor layer 230 both extending in the direction D2, and with the sidewall 136 of the air barrier layer 130 and the sidewall 236 of the first semiconductor layer 230 both extending in the direction D3.

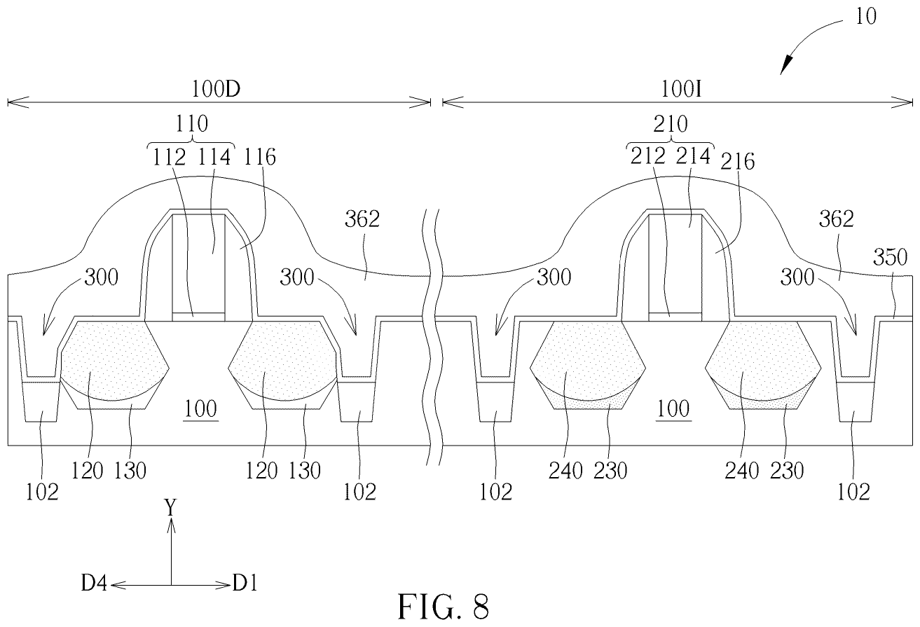

As shown in FIG. 8, a deposition process such as a flowable chemical vapor deposition (FCVD) process is performed, to form a first dielectric material layer 362 on the substrate 100, to overlay the top surface 100t of the substrate 100, to fill in the rest space of each shallow trench 300, and to further overlay the top surface 100t of the substrate 100. In one embodiment, the first dielectric material layer 362 preferably includes a dielectric material with a better filling ability, such as silicon oxide or tetraethyl orthosilicate, but not limited thereto.

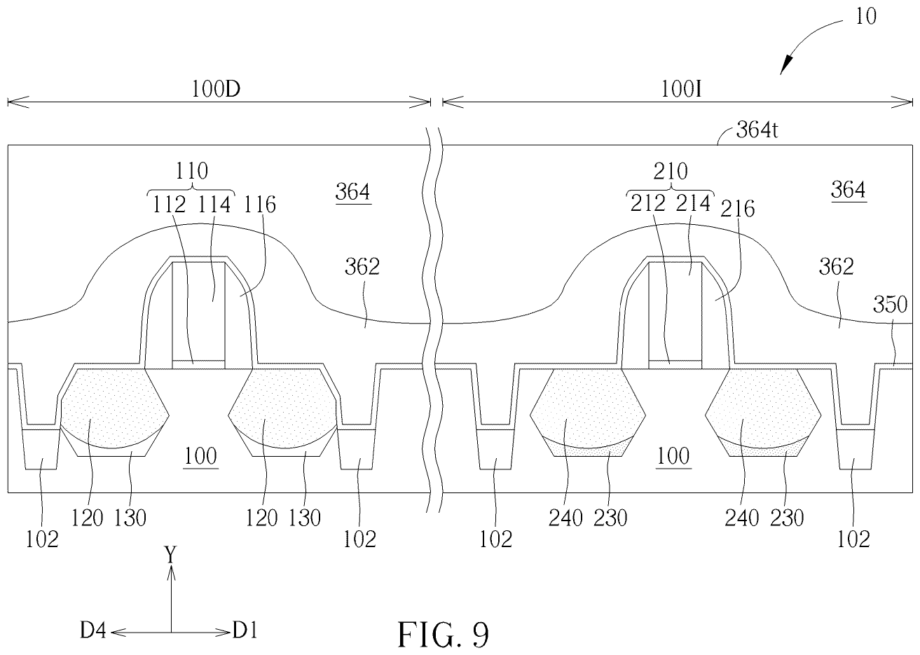

As shown in FIG. 9, another deposition process such as a plasma-enhanced chemical vapor deposition (PECVD) process is performed to form a second dielectric material layer 364 on the first dielectric material layer 326, to obtain an overall flat top surface 364t. In one embodiment, the second dielectric material layer 364 for example includes a dielectric material like silicon oxide or plasma enhanced silicon oxide, but not limited thereto. Following these, a planarization process is performed, to partially remove the second dielectric material layer 364, the first dielectric material layer 362, and the etching stop material layer 350 till exposing the top surfaces of the first gate structure 110 and the second gate structure 210, such that, the second dielectric layer 164, the first dielectric layer 162 and the etching stop layer 150 as shown in FIG. 1 are formed accordingly, with the second dielectric layer 164 and the first dielectric layer 162 together forming the interlayer dielectric layer 160 as shown in FIG. 1. Through the aforementioned steps, the method of fabricating the semiconductor device 10 of the present embodiment is accomplished. In the subsequent process, a replacement metal gate process may be further performed on the semiconductor device 10, by respectively replacing the electrode layers 114, 214 of the first gate structure 110 and the second gate structure 210 with a metal gate (not shown in the drawings), and the metal gate at least includes a work function metal layer (not shown in the drawings) and a metal layer (not shown in the drawings), but not limited thereto.

According to the method of fabricating the semiconductor device 10 in the present embodiment, the first semiconductor layer 230 and the second semiconductor layer 240 with etching selectivity are sequentially formed in each of the recesses 304, 306 by adjusting the growing rate and the lattice plane of the epitaxial growth process, and the first semiconductor layer 230 formed within the dense region 100D is selectively removed while forming the shallow trench isolation 102, and last, the air barrier layer 130 is formed within the dense region 100D, under the second semiconductor layer 240, with the bottom surface 132 and the two sidewalls 134, 136 of the air barrier layer 130 respectively extending toward three directions D1, D2, D3 being different from each other. In this way, the air barrier layer 130 formed within the semiconductor device 10 of the present embodiment is allowable to prevent the substrate currents from leaking from the bottom of the first source/drain structures 120 so as to improve the decreased Isub issue. Thus, the semiconductor device 10 being formed through the fabricating process of the present embodiment will therefore gain a better operating performance and a higher efficiency.

People skilled in the arts should easily realize the semiconductor device and the fabricating method thereof in the present disclosure is not limited to the aforementioned embodiment, and may further include other examples. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

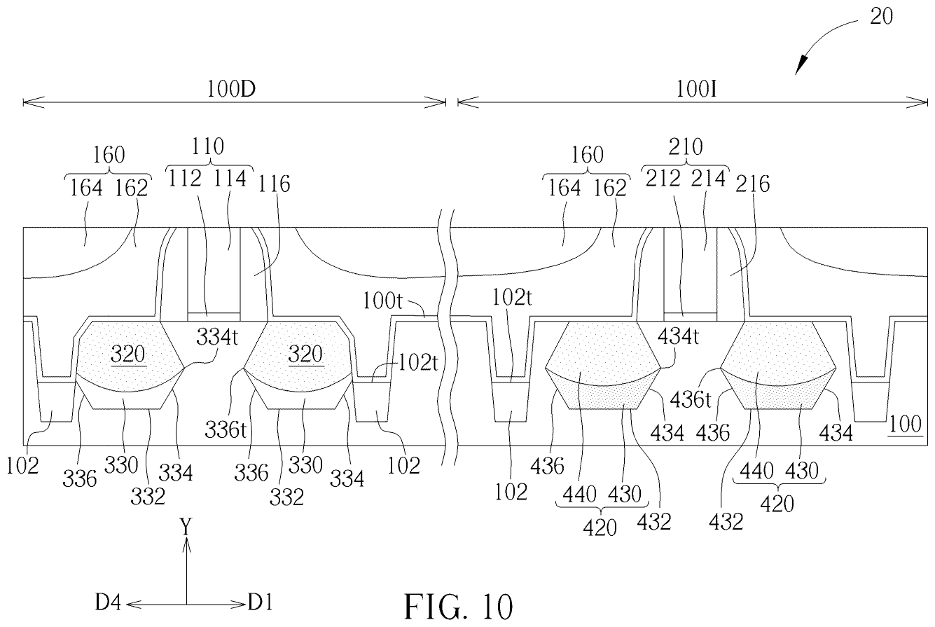

Please refer to FIG. 10, which illustrates a semiconductor device 20 according to a second embodiment of the present disclosure. The structure of the semiconductor device 20 in the present embodiment is substantially the same as that of the semiconductor device 10 in the aforementioned first embodiment, and all the similarities of the two embodiments will not be redundantly described hereinafter. The difference between the present embodiment and the aforementioned first embodiment is mainly in that tips 334t, 336t of two sidewalls 334, 336 of an air barrier layer 330 in the present embodiment are preferably higher than the top surface 102t of the shallow trench isolation 102, and in the same height with the included angles θ3, θ4.

Precisely speaking, after forming the semiconductor structure as shown in aforementioned FIG. 4, a first semiconductor layer 430 is formed within each of the recesses 304, 306 till reaching the same height with the included angles θ3, θ4, by adjusting the growing rate and the lattice plane of the epitaxial growth process, and then, the first semiconductor layer 430 formed within the dense region 100D is completely removed to form the air barrier layer 330. Accordingly, the air barrier layer 330 is also disposed between the substrate 100 and each of the first source/drain structures 320 in the vertical direction “Y”, and includes a bottom surface 332 and two sidewalls 334, 336 respectively extending toward three different directions D1, D2, D3. Then, the first semiconductor layer 430 and a second semiconductor layer 440 disposed in sequence within the iso region 100I will together form a second source/drain structure 420 of the present embodiment, with the first semiconductor layer 430 of the second source/drain structure 420 formed within the iso region 100I and the air barrier layer 330 formed within the dense region 100D both including the same cross-sectional shape, and with the tips 434t, 436t of the two sidewalls 434, 436 of the first semiconductor layer 430 within the iso region 100I also at the same height with the included angles θ3, θ4. That is, in the present embodiment, the bottom surface 332 of the air barrier layer 330 and the bottom surface 432 of the first semiconductor layer 430 are both extended in the direction D1, the sidewall 334 of the air barrier layer 330 and the sidewall 434 of the first semiconductor layer 430 are both extended in the direction D2, and the sidewall 336 of the air barrier layer 330 and the sidewall 436 of the first semiconductor layer 430 are both extended in the direction D3, as shown in FIG. 10.

Through these arrangements, the air barrier layer 330 of the present embodiment is allowable to isolate the possible contacts between the bottom of each first source/drain structure 320 and the substrate 100 in a further effective manner, thereby dramatically blocking the currents leaking from the bottom of the first source/drain structure 320 to the substrate. In this way, the semiconductor device 20 of the present embodiment also enables to avoid the current leakage from the substrate, so as to improve the decreased Isub, and also to enhance the operating performance and the efficiency of the semiconductor device 20.

Overall speaking, the semiconductor device of the present invention additionally arranges an air barrier layer under a source/drain structure having an epitaxial material, with the bottom surface and the two sidewalls of the air barrier layer extending in three different directions, so that, the air barrier layer will effectively isolate the possible contacts between the substrate and the source/drain structure, thereby blocking the currents possibly leaking from the bottom of the source/drain structure to the substrate. Accordingly, the semiconductor device of the present disclosure is allowable to avoid the current leakage from the substrate, so as to improve the decreased Isub, and to gain a better operating performance and a higher efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, comprising at least one shallow trench isolation disposed therein;
a first gate structure, disposed on the substrate;
two first source/drain structures, disposed in the substrate and at two opposite sides of the first gate structure, a side of each of the two first source/drain structures adjacent to the at least one shallow trench isolation; and
an air barrier layer, disposed between the substrate and each of the two first source/drain structures, wherein the air barrier layer comprises a bottom surface and two sidewalls extending in three different directions, respectively.

2. The semiconductor device according to claim 1, wherein a thickness at two ends of the air barrier layer is larger than a thickness at a middle of the air barrier layer.

3. The semiconductor device according to claim 1, wherein the air barrier layer directly contacts each of the two first source/drain structures.

4. The semiconductor device according to claim 1, wherein the at least one shallow trench isolation comprises a top surface being lower than a top surface of the substrate.

5. The semiconductor device according to claim 4, wherein each of the two first source/drain structures comprises an included angle which is located higher than the top surface of the at least one shallow trench isolation in a vertical direction.

6. The semiconductor device according to claim 5, wherein a tip of each of the two sidewalls is lower than the included angle, and is higher than the top surface of the at least one shallow trench isolation in the vertical direction.

7. The semiconductor device according to claim 5, wherein a tip of each of the two sidewalls is higher than the top surface of the at least one shallow trench isolation, and the tip of each of the two sidewalls and the included angle are at a same height in the vertical direction.

8. The semiconductor device according to claim 4, further comprising:
an etching stop layer, disposed on the substrate and overlaying sidewalls of the first gate structure, wherein a portion of the etching stop layer is disposed within the substrate and overlaps the top surface of the at least one shallow trench isolation.

9. The semiconductor device according to claim 4, further comprising:
a second gate structure disposed on the substrate; and
two second source/drain structures disposed in the substrate and at two opposite sides of the second gate structure, wherein each of the two second source/drain structures comprises a first semiconductor layer and a second semiconductor layer stacked in sequence, and the first semiconductor layer comprises a bottom surface and two sidewalls extending in the three different directions, respectively; and
an interlayer dielectric layer disposed on the substrate, the first gate structure and the second gate structure.

10. The semiconductor device according to claim 9, wherein a thickness at two ends of the first semiconductor layer is larger than a thickness at a middle of the first semiconductor layer.

11. The semiconductor device according to claim 9, wherein the first semiconductor layer and air barrier layer are in a same shape.

12. A method of fabricating a semiconductor device, comprising:
providing a substrate, the substrate comprising at least one shallow trench isolation disposed therein;
forming a first gate structure on the substrate;
forming two first source/drain structures in the substrate, at two opposite sides of the first gate structure, wherein a side of each of the two first source/drain structures is adjacent to the at least one shallow trench isolation; and
forming an air barrier layer between the substrate and each of the two first source/drain structures, wherein the air barrier layer comprises a bottom surface and two sidewalls extending in three different directions, respectively.

13. The method of fabricating the semiconductor device according to claim 12, forming the shallow trench isolation further comprising:
forming an insulating layer in the substrate, the insulating layer comprises a top surface being coplanar with a top surface of the substrate; and
partially removing the insulating layer till being lower than the top surface of the substrate, to form the at least one shallow trench isolation.

14. The method of fabricating the semiconductor device according to claim 13, forming the two first source/drain structures and the air barrier layer further comprising:
forming two first recesses in the substrate, at the two opposite sides of the first gate structure, wherein a side of each of the two first recesses is adjacent to the insulating layer;
forming a first semiconductor layer in the two first recesses;
forming a second semiconductor layer on the first semiconductor layer, to fill up the two first recesses; and
completely removing the first semiconductor layer to form the air barrier layer, and to form the two first source/drain structures each comprising the second semiconductor layer.

15. The method of fabricating the semiconductor device according to claim 14, wherein the first semiconductor layer is removed after forming the at least one shallow trench isolation.

16. The method of fabricating the semiconductor device according to claim 14, wherein a germanium concentration of the first semiconductor layer is higher than a germanium concentration of the second semiconductor layer.

17. The method of fabricating the semiconductor device according to claim 14, further comprising:
forming an etching stop layer on the substrate and the first gate structure, wherein a portion of the etching stop layer is formed within the substrate and overlaps a top surface of the at least one shallow trench isolation.

18. The method of fabricating the semiconductor device according to claim 17, further comprising:
forming an etching stop material layer on the substrate, overlaying the first gate structure and the top surface of the at least one shallow trench isolation;
sequentially forming a first dielectric material layer and a second dielectric material layer on the etching stop material layer; and
performing a planarization process, to form the etching stop layer, and an interlayer dielectric layer on the etching stop layer.

19. The method of fabricating the semiconductor device according to claim 14, further comprising:
forming a second gate structure on the substrate;
forming two second recesses in the substrate, at the two opposite sides of the second gate structure; and
forming two second source/drain structures in the two second recesses, respectively, wherein each of the two second source/drain structures comprises the first semiconductor layer and the second semiconductor layer stacked in sequence, and the air barrier layer and the first semiconductor layer of each of the two second source/drain structures are in a same shape.

20. The method of fabricating the semiconductor device according to claim 19, wherein the first semiconductor layer comprises a bottom surface and two sidewalls extending in the three different directions, respectively.
